(19) United States
(12) Patent Application Publication
(10) Pub. No.: US 2010/0310902 A1
(43) Pub. Date: Dec. 9, 2010

(54) DRY ETCHING METHOD, MAGNETO-RESISTIVE ELEMENT, AND METHOD AND APPARATUS FOR MANUFACTURING THE SAME

(75) Inventors: Tomoaki Osada, Kawasaki-shi (JP); Naoko Matsui, Kawasaki-shi (JP); Yoshimitsu Kodaira, Kawasaki-shi (JP); Koji Tsunekawa, Kawasaki-shi (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/819,691

(22) Filed: Jun. 21, 2010

Related U.S. Application Data
(63) Continuation of application No. PCT/JP2008/073045, filed on Dec. 18, 2008.

(30) Foreign Application Priority Data
Dec. 27, 2007 (JP) 2007335702

(51) Int. Cl. H01L 43/08; H01L 43/12; C23C 14/00

(52) U.S. Cl. 428/800; 216/22; 156/345.29; 204/298.02

(57) ABSTRACT

In a method of manufacturing a magneto-resistance element having a multi-layer film including magnetic layers, TaOₓ generated on the surface of the Ta mask is prevented from peeling off when etching is performed on the multi-layer film using an etching gas containing oxygen atoms.

When a Ta mask which is used at the time of dry etching performed on the multi-layer film including magnetic layers with an etching gas containing oxygen atoms is formed by sputtering, the Ar gas pressure is set to be 0.1 Pa to 0.4 Pa.

### CROSS-REFERENCE TO RELATED APPLICATION

This application is a continuation of International Application No. PCT/JP2008/073045, filed on Dec. 18, 2008, which claims the benefit of Japanese Patent Application No. 2007-335702, filed on Dec. 27, 2007. The contents of the aforementioned applications are incorporated herein by reference in their entireties.

### TECHNICAL FIELD

The present invention relates to a dry etching method that uses Ta as a mask and uses an etching gas containing oxygen atoms. In particular, the prevent invention relates to a method of manufacturing a magneto-resistive element in which the element is formed of the multi-layer film that is to be etched and includes a magnetic layer, and a magneto-resistive element that is manufactured by the manufacturing method. In addition, the present invention relates to an apparatus for manufacturing the magneto-resistive element.

### BACKGROUND ART

A magneto-resistive element that is used in an MRAM (Magnetic Random Access Memory) or a sensor of a magnetic head is manufactured by microfabricating a multi-layer film including at least two magnetic layers using dry etching. In a method of performing dry etching on the multi-layer film including the magnetic layers, when methanol is used as an etching gas, for example, corrosive NH₃ is not used. It is not necessary to perform an after-corrosion process after etching. Therefore, it is not necessary to consider the corrosion resistance of an etching apparatus.

For example, when an etching gas containing oxygen atoms, such as methanol (CH₃OH), is used, the surface of a mask made of high-melting-point metal, such as Ta, is oxidized into TaOₓ by oxygen in the etching gas, which results in a reduction in etching rate. Therefore, the mask made of high-melting-point metal, such as Ta, can obtain high selectivity as a mask material. When a base layer of the magneto-resistive element is made of Ta, it is possible to use the base layer made of Ta as an etching stopper layer and effectively manufacture the magneto-resistive element.

In addition, it is possible to form the mask made of Ta on the multi-layer film including the magnetic layers using the same process as that forming other magnetic layers in the sputtering method (see Patent Document 1).

Patent Document 1: Japanese Patent Application Laid-Open (JP-A) No. 2002-38285

### DISCLOSURE OF THE INVENTION

### Problems to be Solved by the Invention

The Ta film having the oxidized surface is used as a protective layer. However, when an etching gas containing oxygen atoms, such as methanol, is used for the multi-layer film including the magnetic layers, the stress of a film is changed when the surface of the mask made of Ta is modified into TaOₓ. The change in stress acts on a compression side and causes the peeling-off of TaOₓ. As a result, it is difficult to perform a high-accuracy microfabrication process and thus product yield is significantly reduced.

An object of the invention is to prevent the peeling-off of TaOₓ that is generated on the surface of a Ta mask when a multi-layer film including a magnetic layer is etched with an etching gas containing oxygen atoms during the manufacture of a magneto-resistive element. Specifically, an object of the invention is to provide a dry etching method using a Ta mask that does not cause the peeling-off of TaOₓ, a method of manufacturing a magneto-resistive element including the dry etching method, and a manufacturing apparatus that can perform the manufacturing method.

### Means for Solving the Problems

According to a first aspect of the invention, a dry etching method includes performing dry etching on a multi-layer film including at least two magnetic layers using methanol as an etching gas, using a Ta layer, whose stress being in the range of −1000 Mpa to 1000 Mpa, that is formed on the multi-layer film by a sputtering method at an Ar gas pressure of 0.1 Pa to 0.4 Pa as a mask.

According to a second aspect of the invention, there is provided a method of manufacturing a magneto-resistive element. The method includes: a film forming step of forming a mask, whose stress being in the range of −1000 MPa to 1000 MPa, made of Ta on a multi-layer film including at least two magnetic layers using a sputtering method at an Ar gas pressure of 0.1 Pa to 0.4 Pa; and an etching step of performing dry etching on the multi-layer film using methanol as an etching gas.

According to a third aspect of the invention, a magneto-resistive element includes a multi-layer film including at least two magnetic layers. The magneto-resistive element is manufactured by the method of manufacturing a magneto-resistive element according to the above-mentioned aspect.

According to a fourth aspect of the invention, an apparatus for manufacturing a magneto-resistive element includes: a film forming unit that can form a film using a sputtering method; an etching unit that can perform dry etching; and a control unit that controls the film forming unit and the etching unit. The control unit controls the film forming unit to perform a step of forming a multi-layer film including at least two magnetic layers using the sputtering method. The control unit controls the film forming unit to perform a step of forming a mask made of Ta on the multi-layer film at an Ar gas pressure of 0.1 Pa to 0.4 Pa. The control unit controls the etching unit to perform an etching step of performing dry etching on the multi-layer film with an etching gas containing oxygen atoms.

### EFFECTS OF THE INVENTION

According to the invention, it is possible to reduce the stress of the mask made of Ta in the range of −1000 MPa to 1000 MPa by setting Ar gas pressure during deposition in a predetermined range.

As a result, even though the multi-layer film including the magnetic layers is etched with an etching gas containing oxygen atoms, TaOₓ generated on the surface of the mask does not peel off and a microfabrication process is performed with high accuracy. Therefore, a good magneto-resistive element is obtained.

### BRIEF DESCRIPTION OF THE DRAWINGS

FIG. 1 is a cross-sectional view schematically illustrating a process of manufacturing a multi-layer film including magnetic layers according to the invention.

FIG. 2 is a cross-sectional view schematically illustrating the structure of an example of a sputtering apparatus for manufacturing the multi-layer film including the magnetic layers according to the invention.

FIG. 3 is a cross-sectional view schematically illustrating the structure of an example of an etching apparatus for performing dry etching on a Ta film and the multi-layer film including the magnetic layers according to the invention.

FIG. 4 is a diagram illustrating the stress of the Ta film when Ar gas pressure is changed in an example of the invention.

### REFERENCE NUMERALS

1: Ta film
2: Al film
3: Ta film
4: Antiferromagnetic layer made of PtMn
5: Pinned layer made of CoFe
6: Insulating layer made of Al₂O₃
7: Free layer made of CoFe
8: NiFe layer
9: Ta film
9a: Ta mask
10: Resist
11: Exhaust system
12: Substrate holder
12a: Rotating mechanism
13, 14: Cathode
13a, 14a: Ta target
13b, 14b: Magnet unit
13c, 14c: Shutter
15: Gate valve
16: Substrate
17: Gas introducing system
17a: Pipe
17b: Flow controller
18: Deposition chamber
20: Substrate holder
21: Exhaust system
22: Magnet for sidewall
23: Gas introducing system
23a, 23d, 23f: Valve
23b: Pipe
23c: Tank
23e: Flow controller
24: Dielectric wall chamber
25: Antenna
26: Transmission path
27: High-frequency power source for plasma
28, 29: Electromagnet
30: High-frequency power source for bias
33: Vacuum chamber

### BEST MODE FOR CARRYING OUT THE INVENTION

Hereinafter, a method of manufacturing a magneto-resistive element of the invention will be described using a method of manufacturing a TMR (Tunnel Magneto-Resistance Effect) element as an example.

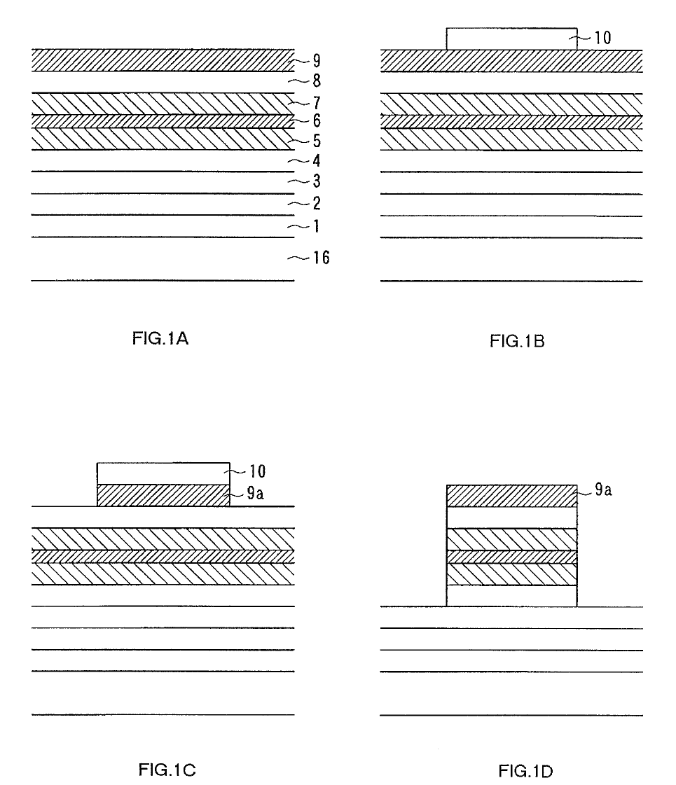

FIG. 1 is a cross-sectional view schematically illustrating a process of manufacturing a TMR element having a multi-layer film including a magnetic layer according to the invention.

First, a Ta film 1, an Al film 2, which is a lower electrode, a Ta film 3, which is a base layer, an antiferromagnetic layer 4 made of PtMn, a pinned layer 5 made of CoFe, an insulating layer 6 made of Al₂O₃, and a free layer 7 made of CoFe are sequentially formed on a substrate 16. In addition, a NiFe layer 8, which is a shield layer, and a Ta film 9a, which is a protective layer, are formed on the free layer. In the invention, all necessary films are formed by a sputtering apparatus, and a Ta film 9 is formed on the uppermost layer under the conditions of an Ar gas pressure of 0.1 Pa to 0.4 Pa [FIG. 1A].

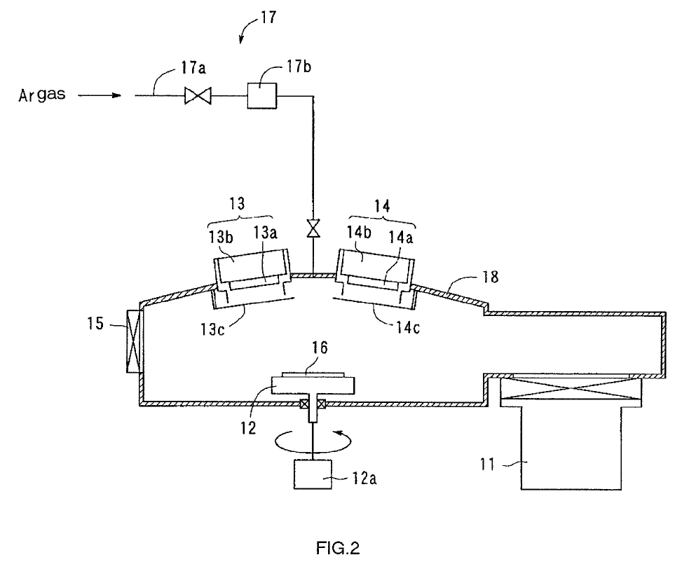

FIG. 2 schematically illustrates the structure of an example of the sputtering apparatus for manufacturing a laminated structure including the multi-layer film shown in FIG. 1A.

A deposition chamber 18 includes an exhaust system 11 that evacuates the deposition chamber and a substrate holder 12 for arranging the substrate 16 on which films will be formed at a predetermined position in the deposition chamber 18. In addition, the deposition chamber 18 includes, for example, a plurality of cathodes 13 and 14 for generating sputtering discharge and a sputtering power source (not shown) for applying a voltage to each of the cathodes 13 and 14.

The deposition chamber 18 is an airtight vacuum chamber, and includes an opening through which the substrate 16 is carried in and out. The opening is closed or opened by a gate valve 15. The exhaust system 11 includes a vacuum pump, such as a turbo-molecular pump, and evacuates the chamber 18.

The deposition chamber 18 is provided with a gas introducing system 17 that introduces gas into the deposition chamber. The gas introducing system 17 introduces a sputtering gas with high sputtering efficiency, specifically, Ar gas. A flow controller 17b as well as a valve is provided in a pipe 17a such that gas can be introduced at a predetermined flow rate.

Each of the cathodes 13 and 14 is a cathode for implementing magnetron sputtering, that is, a magnetron cathode. The cathodes 13 and 14 mainly include, for example, Ta targets 13a and 14a for forming a Ta film and magnet units 13b and 14b that are provided on the rear side of the Ta targets 13a and 14a, respectively. In this case, when the Ta film is used for purposes other than forming a hard mask, the cathodes that are used may be separated.

Although the magnet units 13b and 14b are not shown in detail, the magnet units 13b and 14b are for establishing the orthogonal relation between the electric field and the magnetic field to implement the magnetron motion of electrons. Each of the magnet units 13b and 14b includes a central magnet and a peripheral magnet that surrounds the central magnet.

In some cases, a rotating mechanism 12a of the substrate holder 12 is provided which rotates the magnet units 13b and 14b with respect to the Ta targets 13a and 14a in a stationary state to uniformize erosion.

In addition, shutters 13c and 14c are provided in front of the Ta targets 13a and 14a. The shutters 13c and 14c cover the Ta targets 13a and 14a to prevent the Ta targets 13a and 14a from being stained when the corresponding cathodes 13 and 14 are not used.

In FIG. 2, only two cathodes 13 and 14 for forming a Ta film are shown. However, actually, three or more cathodes including a cathode having a target material other than the material for forming the Ta film are provided.

The sputtering apparatus may be a so-called multi-chamber sputtering apparatus including a plurality of deposition chambers 18 that is airtightly connected to a transfer system chamber in which, for example, a robot for carrying in and out the substrate is provided.

A sputtering power source (not shown) applies a negative DC voltage or a high-frequency voltage to each of the cathodes 13 and 14 and is provided in each of cathodes 13 and 14. And control units (not shown) are provided for controlling power supplied to the cathodes 13 and 14 independently.

Next, in FIG. 1, a resist 10 is formed on the Ta film 9, which is the uppermost layer [FIG. 1B], and the Ta film 9 is etched with a CF₄ gas using the resist 10 as a mask to form a Ta mask 9a. Then, the process proceeds to a microfabrication process [FIG. 1C].

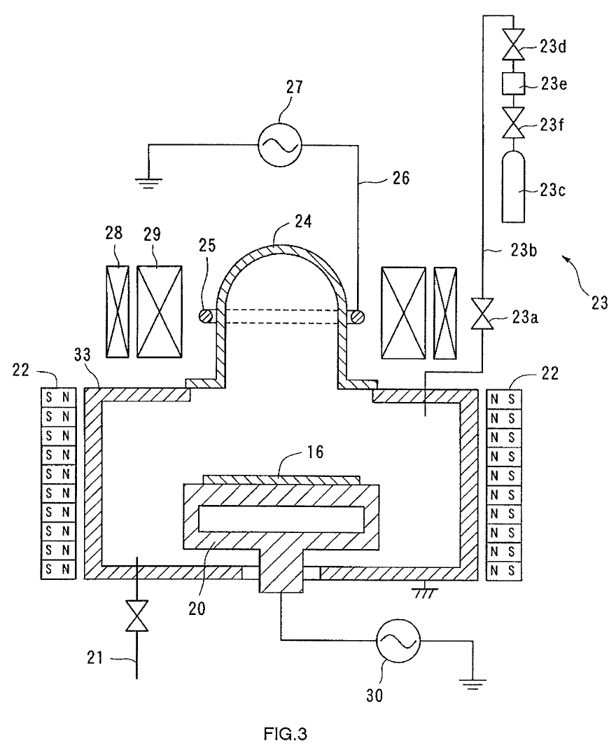

The etching process using the apparatus shown in FIG. 3 will be described using the process shown in FIGS. 1C and 1D as an example.

FIG. 3 is a cross-sectional view schematically illustrating an example of an etching apparatus provided with an ICP (Inductive Coupled Plasma) plasma source that microfabricates the multi-layer film of the TMR element including the magnetic layer using an etching process.

In the invention, the use of the apparatus makes it possible to use, for example, methanol (CH₃OH) as an etching gas containing oxygen atoms and etch the multi-layer film on which a mask made of Ta is formed. The etching process using the apparatus will be described below.

An exhaust system 21 evacuates a vacuum chamber 33, and a gate valve (not shown) is opened. Then, the substrate 16 having the laminated structure shown in FIG. 1B is carried into the vacuum chamber 33 and is then held by a substrate holder 20. Then, a temperature control mechanism 32 maintains the temperature at a predetermined value.

Then, a gas introducing system 23 is operated to introduce an etching gas (CF₄) from a tank 23c storing a CF₄ gas into the vacuum chamber 33 at a predetermined flow rate through a pipe 23b, valves 23a, 23d, and 23f, and a flow controller 23e. The introduced etching gas is diffused into a dielectric wall chamber 24 through the vacuum chamber 33. Plasma is generated in the vacuum chamber 33.

A mechanism that generates the plasma includes the dielectric wall chamber 24, a one-turn antenna 25 that generates a dielectric field in the dielectric wall chamber 24, a high-frequency power source 27 for plasma, and electromagnets 28 and 29 that generate a predetermined magnetic field in the dielectric wall chamber 24. The dielectric chamber 24 is airtightly connected to the vacuum chamber 33 such that the inner space thereof communicates with the vacuum chamber 33, and the high-frequency power source 27 for plasma is connected to the antenna 25 through a matching box (not shown) by a transmission path 26.

In the above-mentioned structure, when a high frequency generated by the high-frequency power source 27 for plasma is supplied to the antenna 25 through the transmission path 26, a current flows through the one-turn antenna 25. As a result, plasma is generated in the dielectric wall chamber 24.

A plurality of magnets 22 for a sidewall is arranged outside of the sidewall of the vacuum chamber 33 in the circumferential direction such that adjacent surfaces among the surfaces facing the sidewall of the vacuum chamber 33 have different magnetic poles. In this way, a cusp magnetic field is generated in the circumferential direction along the inner surface of the sidewall of the vacuum chamber 33 to prevent the diffusion of plasma into the inner surface of the sidewall of the vacuum chamber 33.

At the same time, a high-frequency power source 30 for a bias is operated to apply a self-bias voltage, which is a negative DC voltage, to the substrate 16 to be etched to control ion incident energy from the plasma to the surface of the substrate 16. The plasma that is generated in this way is diffused from the dielectric wall chamber 24 into the vacuum chamber 33 and reaches the vicinity of the surface of the substrate 16. As a result, the surface of the substrate 16 is etched [FIG. 1C].

The etching conditions of the Ta film 9 using the CF₄ gas are as follows:
the flow rate of the etching gas (CF₄): 326 mg/min (50 sccm);
source power: 500 W;
bias power: 70 W;
the pressure of the vacuum chamber 33: 0.8 Pa; and
the temperature of the substrate holder 20: 40° C.

In the apparatus shown in FIG. 3, etching is performed up to the antiferromagnetic layer 4 made of, for example, PtMn with methanol, which is an etching gas, using the Ta mask 9a [FIG. 1D]. This process is the same as the above-mentioned process of operating the gas introducing system 23 to introduce the CF₄ gas as the etching gas into the vacuum chamber 33 except that a methanol gas (not shown) is introduced as the etching gas.

### EXAMPLES

A Ta film to a NiFe layer, which was a shield layer, were formed on a substrate according to the process shown in FIG. 1 using the sputtering apparatus shown in FIG. 2. Then, when a Ta film 9 serving as a mask was formed, Ar gas pressure was changed to form the Ta film 9.

The deposition conditions of the Ta film 9 by sputtering other than the Ar gas pressure were as follows:
T/S distance (the distance between the substrate and a target): 260 mm;
substrate temperature: room temperature;
supplied power: 1 kW; and
the thickness of the Ta film: 100 nm

Then, the Ta film whose Ar gas pressure was changed during deposition was etched by the etching apparatus shown in FIG. 3 using methanol as an etching gas. The etching conditions were as follows:
the flow rate of the etching gas (methanol): 18.75 mg/min (15 sccm);
source power: 1000 W;
bias power: 800 W;
the pressure of the vacuum chamber 33: 0.4 Pa; and
the temperature of the substrate holder 20: 40° C.

However, in the example, methanol was used as the etching gas containing oxygen, but the etching gas is not limited to methanol. For example, other etching gases that oxidize the Ta film, which is a mask, may be used.

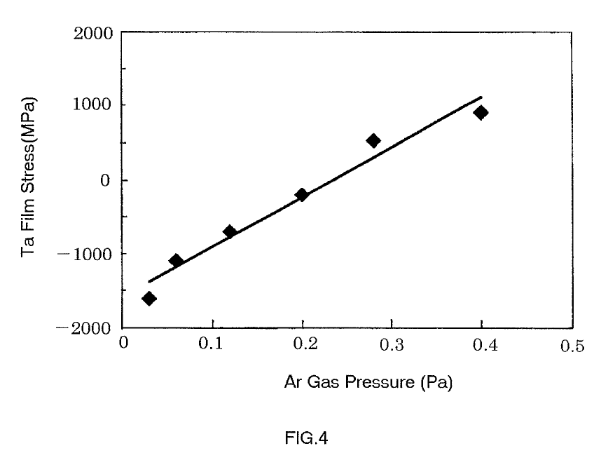

Then, a stress measuring device using an optical technique was used to measure the stress of the substrate before the Ta film 9 was formed, the stress of the substrate after the Ta film was formed, and the stress of the substrate after the Ta film was etched with methanol. Then, the stress of the Ta film was finally calculated from the data. The calculation result is shown in FIG. 4.

The result proved that, when the stress of the formed Ta film was in the range of −1000 MPa to 1000 MPa before it was etched with a methanol gas, the Ta film did not peel off during etching.

Therefore, the result shown in FIG. 4 proved that, when the Ar gas pressure during deposition was in the range of 0.1 Pa to 0.4 Pa, TaOₓ generated on the surface of the mask did not peel off.

In addition, during dry etching with methanol, TaOₓ serving as a mask did not peel off, and the function of TaOₓ as the mask was maintained. As a result, product yield was improved.

1. A dry etching method comprising:
performing dry etching on a multi-layer film including at least two magnetic layers using methanol as an etching gas, using a Ta layer, whose stress being in the range of −1000 MPa to 1000 MPa, that is formed on the multi-layer film by a sputtering method at an Ar gas pressure of 0.1 Pa to 0.4 Pa as a mask.

2. (canceled)

3. A method of manufacturing a magneto-resistive element, comprising:
a film forming step of forming a mask, whose stress being in the range of −1000 MPa to 1000 MPa, made of Ta on a multi-layer film including at least two magnetic layers using a sputtering method at an Ar gas pressure of 0.1 Pa to 0.4 Pa; and
an etching step of performing dry etching on the multi-layer film, using methanol as an etching gas.

4. (canceled)

5. A magneto-resistive element comprising:
a multi-layer film including at least two magnetic layers,
wherein the magneto-resistive element is manufactured by the method of manufacturing a magneto-resistive element according to claim 3.

6. An apparatus for manufacturing a magneto-resistive element comprising:
a film forming unit that can form a film using a sputtering method;
an etching unit that can perform dry etching; and
a control unit that controls the film forming unit and the etching unit,
wherein the control unit controls the film forming unit to perform a step of forming a multi-layer film including at least two magnetic layers using the sputtering method,
the control unit controls the film forming unit to perform a step of forming a mask, whose stress being in the range of −1000 MPa to 1000 MPa, made of Ta on the multi-layer film at an Ar gas pressure of 0.1 Pa to 0.4 Pa, and
the control unit controls the etching unit to perform an etching step of performing dry etching on the multi-layer film, using a methanol gas as an etching gas.

7. A method of dry etching according to claim 1, wherein a target is arranged to be inclined with respect to a substrate, when disposing the Ta layer.

8. A method of manufacturing a magneto-resistive element according to claim 3, wherein a target is arranged to be inclined with respect to a substrate, in the step of disposing a mask made of the Ta.

9. A magneto-resistive element comprising a multi-layer film including at least two magnetic layers, manufactured by the manufacturing method of the magneto-resistive element according to claim 10.

10. A manufacturing apparatus of a magneto-resistive element according to claim 6, wherein a target is arranged to be inclined with respect to the substrate, in the step of forming the mask made of Ta.
